(19) United States
(12) Patent Application Publication
(10) Pub. No.: US 2018/0172778 A1
(43) Pub. Date: Jun. 21, 2018

(54) Derivative Reference-Based Method for Detection of Instability in Power Hardware-in-the-Loop Simulation

(71) Applicant: The Florida State University Research Foundation, Tallahassee, FL (US)

(72) Inventors: James Langston, Crawfordville, FL (US); Karl Schoder, Crawfordville, FL (US)

(73) Assignee: The Florida State University Research Foundation, Tallahassee, FL (US)

(21) Appl. No.: 15/717,081

(22) Filed: Sep. 27, 2017

Related U.S. Application Data
(60) Provisional application No. 62/380,464, filed on Aug. 28, 2016.

(51) Int. Cl. G01R 31/40; H03K 5/24

(52) U.S. Cl. CPC G01R 31/40; H03K 5/24

(57) ABSTRACT

Systems and methods are provided for detecting instability in power hardware-in-the-loop simulations for protection of the equipment being tested. The technology includes computing the magnitude of the time-derivative of reference quantities supplied to a power amplifier and applying a moving average filter. The result from the filter is compared to a threshold for detection of an instability resulting in oscillations of the reference quantities. Once oscillations are detected mitigating steps are taken to protect the device under test.

### CROSS REFERENCE TO RELATED APPLICATIONS

This application claims the benefit of the filing date of U.S. provisional patent application No. 62/380,464 entitled “Derivative Reference-Based Method for Detection of Instability in Power Hardware-in-the-Loop Simulation”, which was filed on Aug. 28, 2016, by the same inventors of this application. That provisional application is hereby incorporated by reference as if fully set forth herein.

### STATEMENT REGARDING FEDERALLY SPONSORED RESEARCH OR DEVELOPMENT

This technology was made with government support under grant N000141410198 awarded by the Office of Naval Research. The government has certain rights in the technology.

### FIELD OF THE TECHNOLOGY

The technology of this application relates generally, but not exclusively, to detecting instability in power hardware-in-the-loop simulations for protection of the equipment being tested.

### BACKGROUND OF THE TECHNOLOGY

Hardware-in-the-loop (HIL) is a form of simulation wherein a hardware device is interfaced to a digital real-time simulator (DRTS), which models the system that the hardware is intended to be connected to in the real world. HIL simulations offer a method to test physical devices under real time operating conditions. Various scenarios can be tested in a controlled environment to evaluate the performance of the device under test (DUT) before it is connected to the actual physical system.

Most HIL simulations are closed-loop meaning that the response of the device is fed back to the DRTS. One type of closed-loop HIL is a Power HIL (PHIL) FIG. 1. PHIL simulations involve interfacing the DRTS with a power device such as a motor, generator, transformer, inverter etc. (DUT). The DRTS and the DUT exchange power over the PHIL interface. In some instances, a digital to analog (D/A) converter, which is included as part of the DRTS provide analog signals scaled down to electronic levels within ±10 Vpk, ±10 mA. In other instances, digital signals may be exchanged. These voltage levels are well below the operating voltage/current range of the DUT, therefore amplifiers and/or actuators are required in PHIL simulations to scale the signals sent from the DRTS to the DUT.

Due to the closed-loop nature of PHIL simulations and the natural delays in the feedback loops, instability is often a problem, and can lead to damage and/or destruction of the equipment involved in the tests. Instabilities in these experiments are often manifested by oscillations in the reference signals that grow in magnitude until some protection system intervenes to stop the experiment. However, the time before a conventional protection system intervenes can be on the order of hundreds of microseconds. Due to the high frequency of the oscillations, these types of instabilities may not be detected by traditional protection elements (e.g. over-current, over-voltage) in time to actually protect the DUT from damage.

Very little has been published regarding protection methods designed to detect instabilities in PHIL systems. Some of the proposed methods to detect these oscillations include over/under frequency protection and harmonic distortion-based protection. However, phase-locked-loop over/under frequency protection or discrete Fourier transform (DFT)-based harmonic distortion protection may react too slowly to prevent damage to the test setup. Conversely, zero-crossing based over/under frequency protection, which could react quickly, is typically impractical in noisy environments and may not detect oscillations superimposed on other waveforms.

It may be advantageous to create a system and/or method that provide(s) fast detection of instabilities in a PHIL simulation that is resistant to typical noise levels.

### BRIEF SUMMARY OF THE TECHNOLOGY

Many advantages will be determined and are attained by one or more embodiments of the technology, which in a broad sense provides systems and methods for detecting instability in PHIL simulations.

One or more embodiments provides a method for detecting instability in a PHIL simulation. The PHIL includes a RTS, a DUT and an amplifier electrically connected between the RTS and the DUT. The method includes computing in a RTS a magnitude of a time-derivative of reference quantities and applying a low pass filter thereto. The method also includes comparing an output from the low pass filter to a threshold for detection of oscillations of the reference quantities. When oscillations are detected a mitigating step is applied to the DUT

One or more embodiments provides a system for detecting instability in a PHIL simulation. The PHIL includes a RTS, a DUT and an amplifier electrically connected between the RTS and the DUT. The system includes a processor based device that includes a non-transitory computer readable medium storing instructions which when executed cause the device to compute, in the RTS, a magnitude of a time-derivative of multiple reference quantities. The instructions cause the device to filter the magnitudes to produce a quantity and compare the produced quantity to a threshold to detect oscillations of the reference quantities. When oscillations are detected the instructions cause the device to protect the DUT.

One or more embodiments provides a system for detecting instability in a PHIL simulation. The PHIL includes a RTS, a DUT and an amplifier electrically connected between the RTS and the DUT. The system includes a time derivative module, stored in memory, that computes a magnitude of a time-derivative of multiple reference quantities. The system also includes a filter module, stored in memory, that filters the magnitudes to produce a quantity. A comparator module, stored in memory, is included that compares the quantity to a threshold to determine oscillations of the reference quantities and a protection module, stored in memory, that protects the DUT when oscillations are detected. The system includes at least one processor that executes the time derivative module, the filter module, the comparator module and the protection module.

The technology will next be described in connection with certain illustrated embodiments and practices. However, it will be clear to those skilled in the art that various modifications, additions and subtractions can be made without departing from the spirit or scope of the claims.

### BRIEF DESCRIPTION OF THE DRAWINGS

For a better understanding of the technology, reference is made to the following description, taken in conjunction with the accompanying drawings, in which like reference characters refer to like parts throughout, and in which:

FIG. 1 illustrates a conventional PHIL simulation;

FIG. 2 illustrates a PHIL simulation in accordance with one or more aspects of the disclosed technology;

FIG. 3 illustrates a graphical representation of a reference voltage and a measured voltage resulting from changes in the system due to non-ideal interfaces;

FIG. 4 illustrates a graphical representation of growing oscillations in a reference voltage and a measured voltage resulting from instability in the system;

FIG. 5 illustrates a graphical representation of several signals related to the rate-of-change of voltage with respect to a threshold value in accordance with one or more aspects of the disclosed technology.

The technology will next be described in connection with certain illustrated embodiments and practices. However, it will be clear to those skilled in the art that various modifications, additions, and subtractions can be made without departing from the spirit or scope of the claims.

### DETAILED DESCRIPTION OF THE TECHNOLOGY

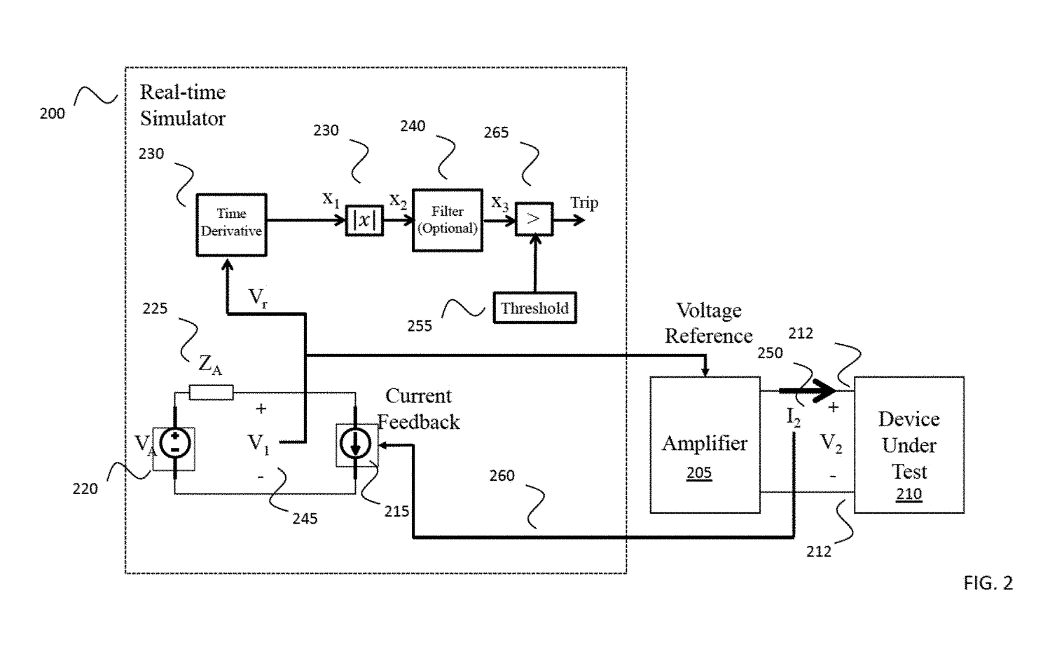

Referring to the figures in detail wherein like reference numerals identify like elements throughout the various figures, there is illustrated in FIGS. 2-5 improved techniques for detection of and protection against instabilities in a PHIL simulation. The technology may include computing the magnitude of the time-derivative of reference quantities (i.e. reference quantities supplied to a power amplifier or actuator forming part of the PHIL interface) and may include applying a filter to produce a quantity that may be applied to a threshold comparator for detection of an instability resulting in oscillations of the reference quantities.

Discussion of an embodiment, one or more embodiments, an aspect, one or more aspects, a feature, one or more features, or a configuration or one or more configurations is intended be inclusive of both the singular and the plural depending upon which provides the broadest scope without running afoul of the existing art and any such statement is in no way intended to be limiting in nature. Technology described in relation to one or more of these terms is not necessarily limited to use in that embodiment, aspect, feature or configuration and may be employed with other embodiments, aspects, features and/or configurations where appropriate.

As illustrated in FIG. 2, the main (hardware) components involved in one or more embodiments of the technology may be a digital real-time simulator (DRTS) 200, a power amplifier (or actuator) 205, and the device under test (DUT) 210. For purposes herein reference to an amplifier 205 and/or an actuator 205 can be used interchangeably such that reference to one can be replaced with reference to the other depending upon the configuration. Additionally, reference to a digital real-time simulator 200 may be considered a reference to a digital, analog or combined digital-analog simulator 200 depending upon the applicable referenced configuration. The DUT's power terminals 212 may be connected to the power amplifier 205 and during the PHIL simulation, they may experience conditions similar to those when operated in the field under actual system conditions. To emulate system conditions, a DRTS 200 may simulate in real time the rest of the system (ROS)(e.g. V_{A}, Z_{A} in FIG. 2) together with the power-interactions of the DUT 210. The response of the DUT 210 may be incorporated into the interface algorithm as a current source 215 and/or voltage source (not illustrated). Additionally, impedances may be incorporated into the interface algorithm. The true replication of the currents and voltages may be achieved through the PHIL interface. The interface conditions and controls information are exchanged to allow the amplifier's power stage to create the ROS conditions and to feedback the DUT response into the real-time simulation of the ROS, operating the overall system as a closed loop for a true PHIL simulation experiment. As indicated in FIG. 2, the DRTS 200 may include various logic elements 230 for computation of the magnitude of the time-derivative of the reference signal and applying a moving average filter 240 (or some other low pass filter 240) to produce a quantity X₃ that can be applied to a threshold comparator 265 for detection of an instability resulting in oscillations of the reference quantities. The logic elements/circuit 230 may be realized in software, hardware, firmware or some combination thereof.

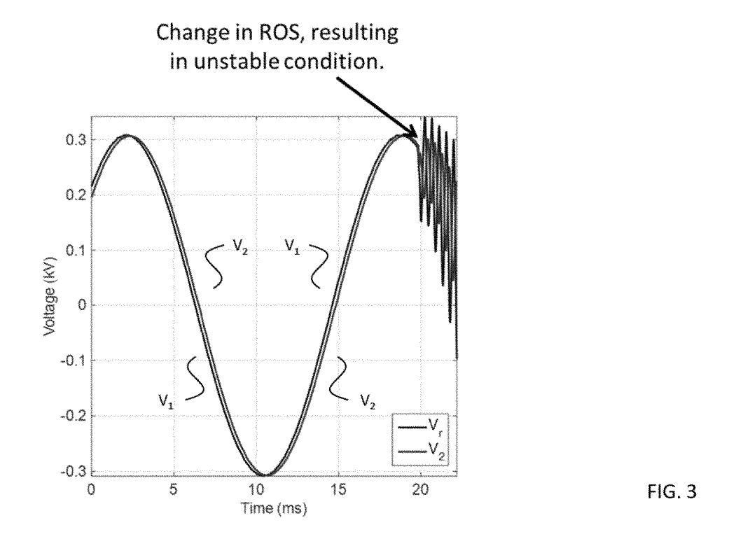

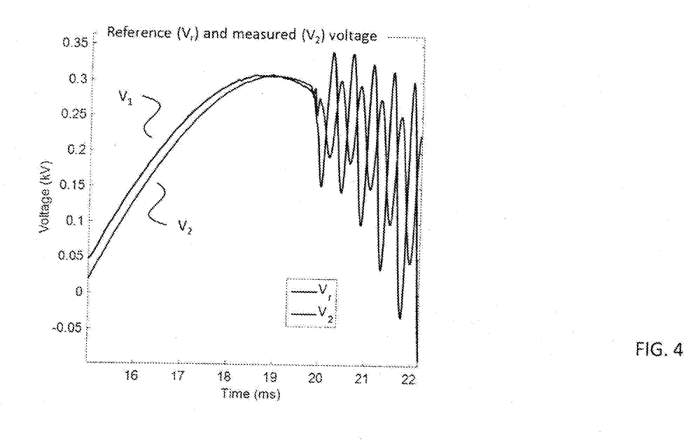

As illustrated in FIG. 3-4, a reference voltage V₁ and the voltage measured across the DUT V₂ may be graphed together to illustrate the results of non-ideal interfaces between various elements of the PHIL.

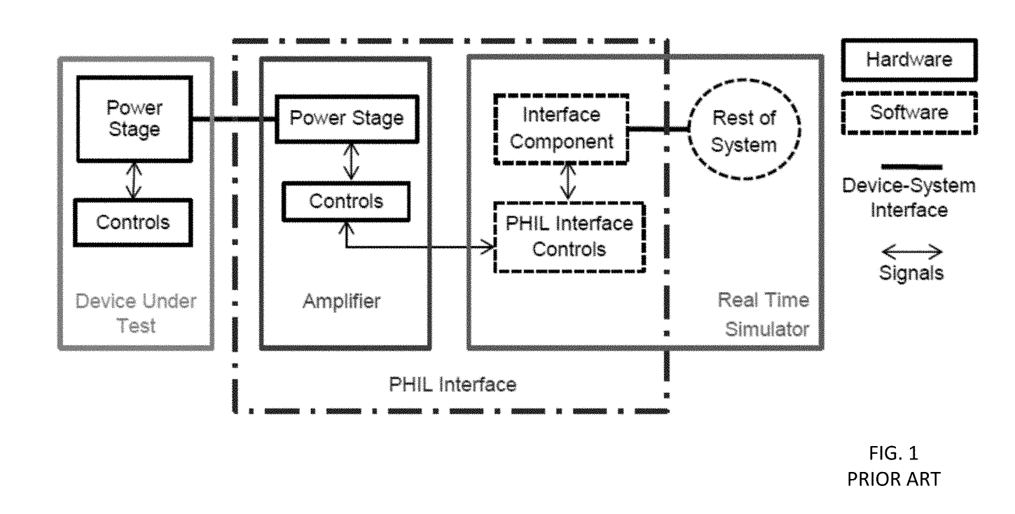

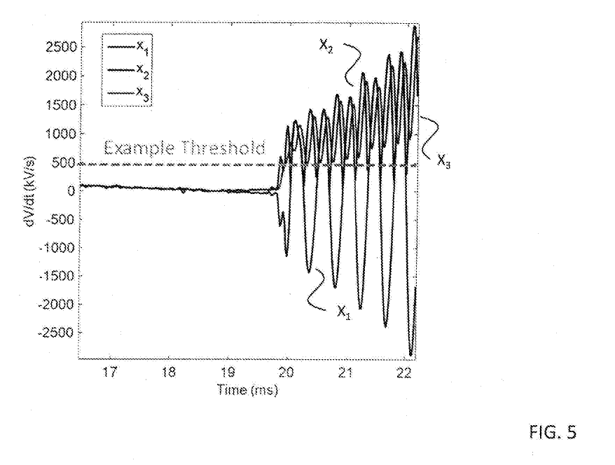

FIG. 5, illustrates the signals as measured at X₁, X₂ and X₃ of FIG. 1. When X₃ crosses the threshold 255, the instability has been identified and mitigating actions may be taken to protect the DUT 210 from damage. While the current embodiment envisions X₃ crossing the threshold 255 as the trigger, the trigger may be configured to be when X₃ reaches the threshold and still fall within a scope of one or more claims. By way of a non-exhaustive list of examples, the action taken to protect the DUT 210 may include removing feedback (reverting to a stable open-loop operation), sending references to zero, opening circuit breakers, etc.

Having thus described one or more preferred embodiments of the technology, advantages can be appreciated. Variations from the described embodiments exist without departing from the scope of the claims. It is seen that systems and methods are provided for detecting instability in power hardware-in-the-loop simulations for protection of equipment being tested. Although specific embodiments have been disclosed herein in detail, this has been done for purposes of illustration only, and is not intended to be limiting with respect to the scope of the claims, which follow. It is contemplated by the inventors that various substitutions, alterations, and modifications may be made without departing from the spirit and scope of the technology as defined by the claims. Other aspects, advantages, and modifications are considered within the scope of the following claims. The claims presented are representative of the technology disclosed herein. Other, unclaimed technology is also contemplated. The inventors reserve the right to pursue such technology in later claims.

Insofar as embodiments described above are implemented, at least in part, using a computer system, it will be appreciated that a computer program for implementing at least part of the described methods and/or the described systems is envisaged as an aspect of the technology. The computer system may be any suitable apparatus, system or device, electronic, optical, or a combination thereof. For example, the computer system may be a programmable data processing apparatus, a computer, a Digital Signal Processor, an optical computer or a microprocessor. The computer program may be embodied as source code and undergo compilation for implementation on a computer, or may be embodied as object code, for example.

It is also conceivable that some or all of the functionality ascribed to the computer program or computer system aforementioned may be implemented in hardware, for example by one or more application specific integrated circuits and/or optical elements. Suitably, the computer program can be stored on a carrier medium in computer usable form, which is also envisaged as an aspect of the invention. For example, the carrier medium may be solid-state memory, optical or magneto-optical memory such as a readable and/or writable disk for example a compact disk (CD) or a digital versatile disk (DVD), or magnetic memory such as disk or tape, and the computer system can utilize the program to configure it for operation. The computer program may also be supplied from a remote source embodied in a carrier medium such as an electronic signal, including a radio frequency carrier wave or an optical carrier wave.

It is accordingly intended that all matter contained in the above description or shown in the accompanying drawings be interpreted as illustrative rather than in a limiting sense. It is also to be understood that the following claims are intended to cover all of the generic and specific features of the technology as described herein, and all statements of the scope of the technology which, as a matter of language, might be said to fall there between.

Having described the technology, what is claimed as new and secured by Letters Patent is:

1. A method for detecting instability in a power hardware-in-the-loop (PHIL) simulation; wherein the PHIL includes a real-time simulator (RTS) a device under test (DUT) and an amplifier electrically connected between the RTS and the DUT, the method comprising:
computing in a RTS a magnitude of a time-derivative of a reference quantity and applying a low pass filter thereto;
comparing an output from the low pass filter to a threshold for detection of oscillations of the reference quantities; and,
when oscillations are detected, applying a mitigating step to the DUT.

2. The method according to claim 1 wherein the low pass filter is a moving average filter.

3. The method according to claim 1 wherein oscillations are detected when the output from the low pass filter exceeds the threshold.

4. The method according to claim 1 wherein oscillations are detected when the output from the low pass filter reaches the threshold.

5. The method according to claim 1 wherein the mitigating step includes disconnecting the DUT.

6. The method according to claim 1 wherein the mitigating step includes changing the reference quantity to zero.

7. The method according to claim 1 wherein the reference quantity includes a measured voltage across the DUT.

8. The method according to claim 1 wherein the reference quantity includes a measured DUT current.

9. The method according to claim 1 wherein the RTS is a digital RTS.

10. A system for detecting instability in power hardware-in-the-loop (PHIL) simulations; wherein the PHIL includes a real time simulator (RTS) a device under test (DUT) and an amplifier electrically connected between the RTS and the DUT, the system comprising:
a processor based device comprising a non-transitory computer readable medium storing instructions which when executed cause the device to:
compute, in the RTS, a magnitude of a time-derivative of a plurality of reference quantities, filter the magnitudes to produce a quantity; compare the produced quantity to a threshold to detect oscillations of the reference quantities and when oscillations are detected protecting the DUT.

11. The system according to claim 10 wherein oscillations are detected when the produced quantity exceeds the threshold.

12. The system according to claim 10 wherein oscillations are detected when the produced quantity reaches the threshold.

13. The system according to claim 10 wherein the protecting the DUT includes disconnecting the DUT.

14. The system according to claim 10 wherein the protecting the DUT includes changing at least one of the plurality of reference quantities to zero.

15. The system according to claim 10 wherein at least one of the plurality of reference quantities includes a measured voltage across the DUT.

16. The system according to claim 10 wherein at least one of the plurality of reference quantities includes a measured DUT current.

17. The system according to claim 10 wherein the RTS is a digital RTS.

18. A system for detecting instability in a power hardware-in-the-loop (PHIL) simulation; wherein the PHIL includes a real time simulator (RTS) a device under test (DUT) and an amplifier electrically connected between the RTS and the DUT, the system comprising:
a time derivative module, stored in memory, that computes a magnitude of a time-derivative of a plurality of reference quantities;
a filter module, stored in memory, that filters the magnitudes to produce a quantity;
a comparator module, stored in memory, that compares the quantity to a threshold to determine oscillations of the reference quantities
a protection module, stored in memory, that protects the DUT when oscillations are detected; and
at least one processor that executes the time derivative module, the filter module, the comparator module and the protection module.

19. The system according to claim 18 wherein the RTS is a digital RTS.

20. The system according to claim 18 wherein the protection module disconnects the DUT from the RTS.
